(19) United States
(12) Patent Application Publication
(10) Pub. No.: US 2011/0269263 A1
(43) Pub. Date: Nov. 3, 2011

(54) METHOD FOR IMPLANTING IMPURITIES INTO A SUBSTRATE AND METHOD FOR MANUFACTURING A SOLAR CELL USING THE SAME

(76) Inventor: Yoon-Mook KANG, Gyeonggi-do (KR)

(21) Appl. No.: 12/959,885

(22) Filed: Dec. 3, 2010

(30) Foreign Application Priority Data
May 3, 2010 (KR) 2010-0019698

(51) Int. Cl. H01L 31/0224; H01L 21/22

(52) U.S. Cl. 438/98; 438/535; 257/E21.135; 257/E31.124

(57) ABSTRACT

In a method for implanting impurities into a substrate and a method for manufacturing a solar cell using the method, a substrate is dipped into a first solution including a first impurity, and a laser is irradiated to a first region of the substrate dipped into the first solution is irradiated with laser to implant a first dopant generated from the first impurity into the first region. Accordingly, the first dopant generated from the first impurity is implanted into the substrate at room temperature to improve reliability for implanting the first dopant.

PRIORITY STATEMENT

This application claims priority, under 35 U.S.C. §119, to Korean Patent Application No. 2010-19698 filed on Mar. 5, 2010 in the Korean Intellectual Property Office (KIPO), the contents of which are herein incorporated by reference in their entirety.

### BACKGROUND OF THE INVENTION

1. Field of the Invention

The present invention relates to a method for implanting impurities into a substrate and a method for manufacturing a solar cell using the method. More particularly, the present invention relates to a method for implanting impurities into a substrate for manufacturing a solar cell and a method for manufacturing a solar cell using the method.

2. Description of the Related Art

A semiconductor may be defined as a p-type semiconductor or an n-type semiconductor according to the type of impurities implanted into the substrate. The substrate that forms the p-type semiconductor or the n-type semiconductor typically includes silicon (Si) or germanium (Ge).

Conventional methods for implanting the impurities (Hereinafter, “implanting method”) include thermal diffusion and ion implantation. In the thermal diffusion method, a wafer and a gas are heated to a high temperature and the heated gas is diffused into the heated wafer. In the ion implantation method, high energy is provided to dopants to form an ion beam and the ion beam is implanted into a wafer. Generally, the thermal diffusion method and the ion implantation method are performed at a high temperature of at least about 850° C. The impurities are implanted at a high concentration in the thermal diffusion method and the ion implantation method to manufacture a semiconductor having a good electric conductivity. However, the semiconductor may have crystal defects because the impurities are implanted at a high temperature of at least about 850° C. The presence of crystal defects increases the resistance of the semiconductor, generally lowering the quality of the semiconductor.

A solar cell is an energy conversion element that converts the energy in sunlight into electric energy using photovoltaic effect. When sunlight is irradiated to a substrate of a solar cell, electrons and holes are created inside of the solar cell. The electrons and the holes respectively move to positive and negative poles of the solar cell to generate a photo-electromotive force which is caused by a potential difference between the positive and negative poles. When the solar cell is loaded, a current is generated. The solar cell includes the p-type semiconductor as the positive pole and the n-type semiconductor as the negative pole. When the solar cell is manufactured by the thermal diffusion method or the ion implantation method, the solar cell is manufactured using materials that demonstrate thermal stability at high temperature ranges. The crystal defects present in the solar cell may decrease energy efficiency of the solar cell.

### SUMMARY OF THE INVENTION

The present invention provides a method for implanting impurities into a substrate at a room temperature.

The present invention also provides a method for manufacturing a solar cell using the method.

According to one aspect of the present invention, there is provided a method for implanting impurities into a substrate. In the method, a substrate is dipped into a first solution including a first impurity. A laser beam is irradiated a first region of the substrate that is dipped into the first solution to implant a first dopant generated from the first impurity into the first region.

Each of the dipping of the substrate and to the irradiating the laser beam may be performed at room temperature.

The laser beam may be irradiated to an entire surface of the substrate to further form a doped layer on substantially the entire surface of the substrate before implanting the first dopant.

The method may further include forming an insulating layer on the substrate before dipping the substrate into the first solution. The first dopant may diffuse into the first region from which the insulating layer is removed by the laser.

The substrate including the first region doped with the first dopant may be dipped into a second solution including a second impurity. The laser beam may be irradiated to a second region adjacent to the first region of the substrate while the substrate is dipped into the second solution to implant a second dopant generated from the second impurity into the second region.

In another aspect of the present invention, there is provided a method for manufacturing a solar cell using the method. In the method, a substrate is dipped into a first solution including a first impurity. A laser beam is irradiated to a first surface of the substrate dipped into the first solution to form a first doped region doped with a first dopant generated from the first impurity. A first electrode is formed on the base substrate and the first electrode makes contact with the first doped region. A second electrode is formed on the base substrate.

An insulating layer may be further formed on the first surface of the base substrate before dipping the substrate into the first solution. The insulating layer may be partially removed by the laser and the first dopant may be diffused into the base substrate to form the first doped region.

The substrate including the first doped region may be dipped into a second solution including a second impurity different from the first impurity. The laser beam is irradiated to the substrate while the substrate is dipped into the second solution to implant a second dopant generated from the second impurity.

The first and/or second impurities may be implanted into the base substrate at room temperature so that crystal defects of a semiconductor may be decreased. Thus, reliability of manufacturing the semiconductor and an efficiency of the solar cell may be improved. In addition, a manufacturing device of the semiconductor may include a container receiving a solution and a laser providing device, and the first doped region may be locally formed using the laser without a mask, so that productivity of a semiconductor substrate may be improved.

### BRIEF DESCRIPTION OF THE DRAWINGS

The above and other features and advantages of the present invention will become more apparent by describing in detailed example embodiments thereof with reference to the accompanying drawings, in which:

FIG. 1 is a perspective view illustrating a solar cell manufactured by a method according to an example embodiment of the present invention;

FIG. 2 is a cross-sectional view taken along a line I-I′ in FIG. 1;

FIGS. 3A to 3E are cross-sectional views illustrating the method of manufacturing the solar cell shown in FIG. 2;

FIGS. 4A to 4C are cross-sectional views illustrating a method of manufacturing a solar cell according to another example embodiment of the present invention;

FIG. 5A is a perspective view illustrating a solar cell manufactured by a method according to still another example embodiment of the present invention;

FIG. 5B is a perspective view illustrating a rear side of the solar cell shown in FIG. 5A;

FIG. 6 is a cross-sectional view illustrating the method of manufacturing the solar cell shown in FIGS. 5A and 5B;

FIG. 7 is a perspective view illustrating a solar cell manufactured by a method according to still another example embodiment of the present invention;

FIG. 8 is a cross-sectional view taken along a line II-II′ in FIG. 7;

FIG. 9 is a cross-sectional view illustrating the method of manufacturing the solar cell shown in FIG. 8;

FIG. 10A is a perspective view illustrating a solar cell manufactured by a method according to still another example embodiment of the present invention;

FIG. 10B is a perspective view illustrating a rear side of the solar cell shown in FIG. 10A;

FIG. 10C is a cross-sectional view taken along a line III-III′ in FIG. 10B; and

FIGS. 11A and 11B are cross-sectional views illustrating the method of the solar cell shown in FIG. 10C.

### DETAILED DESCRIPTION OF THE INVENTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

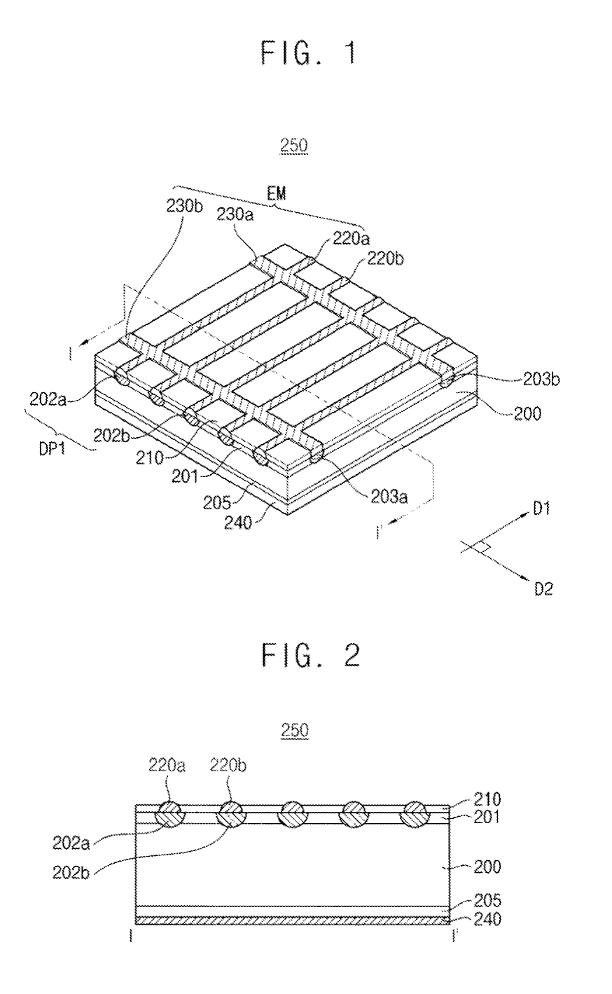

FIG. 1 is a perspective view illustrating a solar cell manufactured by a method according to an example embodiment of the present invention. FIG. 2 is a cross-sectional view taken along a line I-I′ in FIG. 1.

Referring to FIGS. 1 and 2, a solar cell 250 according to the present example embodiment includes a base substrate 200, a first electrode EM, a second electrode 240 and an insulating layer 210. The base substrate 200 includes a first doped region DP1, a first doped layer 201 and a second doped layer 205. The first doped region DP1 includes first doped lines 202a and 202b and second doped lines 203a and 203b. The first electrode EM, the second electrode 240 and the insulating layer 210 are formed on the base substrate 200 including the first doped region DP1, the first doped layer 201 and the second doped layer 205.

The base substrate 200 may include a p-type semiconductor.

The first doped layer 201 may include an n-type semiconductor having a first dopant. The first doped layer 201 is formed on a first surface of the base substrate 200. Sun light is incident on a first surface of the solar cell 250 (which may be the top surface in FIG. 1). A PN junction structure of the solar cell 250 may be defined as the first doped layer 201 is formed on the base substrate 200. The first doped layer 201 substantially receives the sunlight and functions as an emitter. The first doped layer 201 covers the entire first surface of the base substrate 200 except for where the first doped region DP1 is present. Thus, in plan view, the first doped layer 201 has a grid formed by the first doped region DP1. The first doped layer 201 may be disposed on the first surface of the base substrate 200.

The first doped region DP1 may include an n+ type semiconductor which is an n-type semiconductor doped with impurities of a higher concentration than the first dopant doped into the first doped layer 201. The concentration of a first dopant in the first doped region DP1 is higher than that of the first dopant in the first doped layer 201. The first doped region DP1 makes direct contact with the first electrode EM so that a contact resistance between the first electrode EM and the first doped layer 201 may be reduced. The first dopant may include an element in Group 13 including boron (B), aluminum (Al), etc., or an element in Group 15 including phosphorus (P), arsenic (As), etc. In the present example embodiment, the first dopant includes a Group 15 element.

As mentioned above, the first doped region DP1 includes a plurality of first doped lines 202a and 202b and a plurality of second doped lines 203a and 203b. The first doped lines 202a and 202b extend in a first direction D1 and are spaced apart from each other in a second direction D2. The second doped lines 203a and 203b extend in the second direction D2 to cross the first doped lines 202a and 202b and are spaced apart from each other in the first direction D1. The first doped lines 202a and 202b are connected to the second doped lines 203a and 203b at intersections between the first doped lines 202a and 202b and the second doped lines 203a and 203b.

The first electrode EM includes a plurality of finger lines 220a and 220b and a plurality of bus lines 230a and 230b. The first electrode EM may include silver (Ag). The finger lines 220a and 220b are disposed on the first doped lines 202a and 202b to directly contact the first doped lines 202a and 202b. The finger lines 220a and 220b extend in the first direction D1 and are spaced apart from each other in the second direction D2. The bus lines 230a and 230b are disposed on the second doped lines 203a and 203b to directly contact the second doped lines 203a and 203b. The bus lines 230a and 230b extend in the second direction D2 and are spaced apart from each other in the first direction D1. The finger lines 220a and 220b and the bus lines 230a and 230b are connected to each other at intersections between the finger lines 220a and 220b and the bus lines 230a and 230b.

The insulating layer 210 is formed on the first doped layer 201. The insulating layer 210 may function as a reflection blocking layer that minimizes reflection of the sunlight that is incident on the first doped layer 201. In addition, the insulating layer 210 may protect the base substrate 200. The insulating layer 210 may include silicon nitride. The insulating layer 210 may be formed in regions between the finger lines 220a and 220b adjacent to each other and the bus lines 230a and 230b adjacent to each other. When the first doped layer 201 is formed to accommodate the grid of the first doped region DP1, the insulating layer 210 may also be formed around the grid in plan view. The insulating layer 210 is disposed on the same plane as the first electrode EM so that the first electrode EM directly contacts the first doped region DP1 and the insulating layer 210 directly contacts the first doped layer 201.

The second doped layer 205 covers substantially the entire second surface of the base substrate 200. The second surface is a surface of the base substrate 200 facing the first surface. The second doped layer 205 includes a p+ type semiconductor. Electrons generated in the base substrate 200 by the sunlight drift to the first doped layer 201. In addition, holes generated in the base substrate 200 may be pulled by the second doped layer 205 so that the second doped layer 205 may prevent the holes from combining with the electrons and may prevent the electrons from being annihilated.

The second electrode 240 is formed on the second surface of the base substrate 200. The second electrode 240 makes contact with the second doped layer 205. For example, the second electrode 240 is formed on a surface of the second doped layer 205 that is opposite the surface that contacts the base substrate 200 (the “contact surface”), to be an electrode opposite to the first electrode EM. The contact surface directly makes contact with the second surface of the base substrate 200. The second electrode 240 may include silver (Ag).

In one embodiment, the base substrate 200 may include an n-type semiconductor, the first doped layer 201 may include a p-type semiconductor, the first doped region DP1 may include a p+ type semiconductor, and the second doped layer 205 may include an n+ type semiconductor.

The solar cell 250 may generate electric power as follows. When sunlight is irradiated to the first doped layer 201, the holes and the electrons are generated in the base substrate 200 due to the energy from the sunlight. The holes drift to the second doped layer 205 by an electric field generated in a PN junction between the base substrate 200 and the first doped layer 201. The electrons drift to the first doped layer 201 by the electric field. The electrons that drift to the first doped layer 201 accumulate in the first electrode EM via the first doped region DP1. The holes that drift to the second doped layer 205 accumulate in the second electrode 240. A potential difference is generated in the solar cell 250 by the electrons and the holes respectively accumulating in the first and second electrodes EM and 240. Thus, the solar cell 250 may generate electric power.

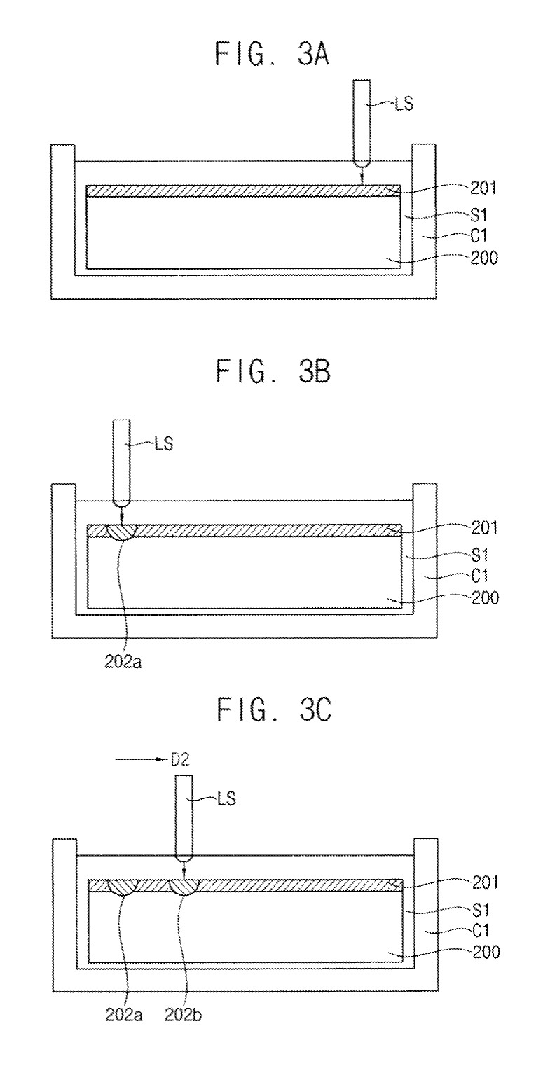

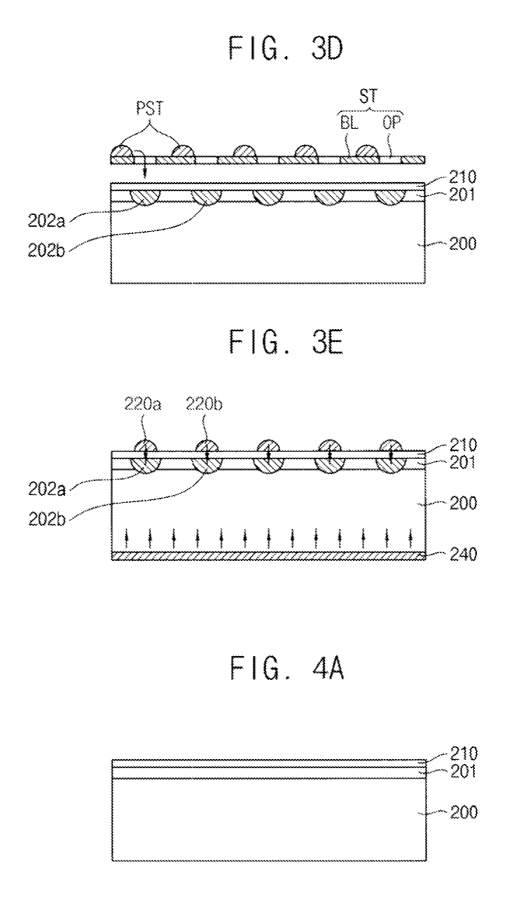

FIGS. 3A to 3E are cross-sectional views illustrating the method of manufacturing the solar cell shown in FIG. 2.

Referring to FIG. 3A, the base substrate 200 is dipped into a first solution S1 by being placed in a first container C1 that holds a first solution S1. The process of dipping the base substrate 200 into the first solution S1 may be performed at room temperature. “Room temperature,” as used herein, refers to a temperature range between about 15° C. to about 100° C.

The first solution S1 includes a first impurity that is different from main elements forming the base substrate 200. When the first dopant includes phosphorus (P), examples of the first impurity may include phosphorus pentoxide (P₂O₅), phosphoric acid (H₃PO₄), triethyl phosphite ((C₂H₅O)₃P) or trimethyl phosphite ((CH₃O)₃P), etc.

A laser beam is irradiated to the base substrate 200 that is immersed in the first solution S1 using a laser irradiating device LS. The laser irradiation may be done at room temperature. The laser beam has a pulse width of a pico second unit, and the range of the pulse width of the laser beam may be more than or equal to about 0.1×10⁻¹² seconds and less than about 1.0×10⁻⁹ seconds. Preferably, the pulse width may be between about 5×10⁻¹² seconds to about 1.5×10⁻¹¹ seconds.

As the laser beam is irradiated to the first surface of the base substrate 200 for a predetermined period, compounds forming the base substrate 200 react with a first impurity of the first solution. By reacting with the first impurity, the base substrate 200 transitions into a state in which the first impurity is easily implanted into the base substrate 200. In addition, the first dopant is separated from the first impurity by the laser beam. The first dopant diffuses into the base substrate 200 so that the first impurity is implanted into the first surface of the base substrate 200.

For example, the laser irradiating device LS may irradiate substantially the entire first surface of the base substrate 200 to form the first doped layer 201. For example, the laser beam is irradiated to the base substrate 200 while the laser irradiating device LS continuously moves along the first direction D1. Then, the laser irradiating device LS moves in the second direction D2 to be disposed adjacent to a region that has already irradiated the laser beam. Then, the laser beam is irradiated to the base substrate 200 while the laser irradiating device LS that shifted in the second direction D2 continuously moves along the first direction D1. The laser irradiating device LS's shifting in the second direction D2 and traversing in the first direction D1 are repeatedly performed, so that the laser irradiation is achieved to over substantially the whole first surface of the base substrate 200, and the first dopant generated from the first impurity may be implanted over an entire surface of the first surface to form the first doped layer 201.

Alternatively, the first doped layer 201 may be formed by a thermal diffusion method or an ion implantation method which is a typical method for implanting impurities. The first doped layer 201 is less affected by a temperature higher than about 80° C. because the first doped layer 201 is formed on the base substrate 200 before other components of the solar cell 250 are formed. In addition, the first dopant of a high concentration is implanted into the first doped layer 201 corresponding to a contact region with the first electrode EM to form the first doped region DP1, and thus the first dope layer 201 is less affected by crystal defects.

Referring to FIG. 3B, the laser irradiating device LS irradiates the first surface of the base substrate 200 including the first doped layer 201 formed on the base substrate 200 and immersed in the first solution S1 with the laser beam. The laser beam is irradiated to the base substrate 200 while the laser irradiating device LS continuously moves along the first direction D1, so that the first dopant may be selectively implanted in regions where the laser has already been irradiated. This way, a first line 202a extending in the first direction D1 may be formed.

After the laser irradiating device LS shifts in the second direction D2, the laser beam is irradiated to the base substrate 200 while continuously moving along the first direction D1, so that a second line 202b of the first doped lines 202a and 202b may be formed. The second line 202b is spaced apart from the first line 202a in the second direction D2. The shifting in the section direction D2 and the traversal in the first direction D1 described above are repeatedly performed, so that a plurality of the first doped lines 202a and 202b may be formed.

The laser beam is irradiated to the base substrate 200 that has the first doped lines 202a and 202b formed thereon while the base substrate 200 remains immersed in the first solution S1. The laser irradiating device LS continuously moves along the second direction D2, so that a first line 203a of the second doped lines 230a and 230b may be formed. In addition, after the laser irradiating device LS shifts in the first direction D1, the laser beam is irradiated to the base substrate 200 that already has the first line 203a formed thereon while the laser irradiating device LS moves along the second direction D2 to form a second line 203b of the second doped lines 230a and 203b. The second line 203b is spaced apart from the first line 203a in the first direction D1.

In the manner described, the first doped region DP1 including the first doped lines 202a and 202b and the second doped lines 203a and 203b may be formed on the first surface of the base substrate 200. The first surface of the base substrate 200 may be entirely covered by the first doped region DP1 and the first doped layer 201.

When the first doped layer 201 is formed using the first solution S1 and the laser, all steps for forming the first doped layer 201 and the first doped region DP1 may be performed while the first doped layer 201 is immersed in the first container C1.

Referring to FIG. 3D, the insulating layer 210 is formed on the base substrate 200 including the first doped layer 201 and the first doped region DP1 formed on the base substrate 200. The insulating layer 210 may be formed on the first surface of the base substrate 200 to make contact with the first doped layer 201 and the first doped region DP1. The insulating layer 210 is formed after the base substrate 200 (or at least the relevant portion thereof) is taken out of the first solution S1.

The first electrode EM is formed on the first surface of the base substrate 200 including the insulating layer 210 via a screen printing method. During a typical screen printing process, a stencil ST is disposed over the base substrate 200 including the insulating layer 210. The stencil ST includes an opening portion OP facing the first doped region DP1 and a blocking portion BL facing the first doped layer 201. The opening portion OP in the stencil ST may be designed based on a shape of the first doped region DP1. An electrode material PST is disposed on the blocking part BL of the stencil ST. The electrode material PST includes silver (Ag) and may be in the form of a paste. When the electrode material PST moves along the first direction D1, the electrode material PST is transferred from the blocking part BL to the opening portion OP and the electrode material PST transferred to the opening portion OP is disposed on the insulating layer 210. The electrode material PST is disposed on the insulating layer 210 corresponding to the first doped region DP1 using the above screen printing method. After the electrode material PST is disposed on the insulating layer 210 and is heated, the first electrode EM is formed by heating the electrode material PST disposed on the insulating layer 210. The shape of the first electrode EM is substantially the same as that of the first doped region DP1.

Referring to FIG. 3E, the second electrode 240 is formed on the second surface of the base substrate 200 using a silver (Ag) paste. The silver paste may be directly coated on the second surface of the base substrate 200 to form the second electrode 240.

Then, the base substrate 200 having the first and second surfaces is heated. The first electrode EM is formed on the insulating layer 210 which is formed on the first surface of the base substrate 200, and the second electrode 240 is formed on the second surface of the base substrate 200.

By heating the base substrate 200, a metal of the first electrode EM is diffused into the insulating layer 210. The insulating layer 210 corresponding to a contact portion with the first electrode EM does not insulate the first electrode EM from the first doped region DP1 and thus, the first electrode EM is electrically connected to the first doped region DP1. Thus, the first electrode EM is electrically connected to the first doped region DP1, and substantially makes contact with the first doped region DP1 without separate patterning of the insulating layer 210.

In addition, a metal of the second electrode 240 is diffused into the second surface of the base substrate 200 by heating the base substrate 200. The second doped layer 205 is formed by the metal of the second electrode 240 diffused into the second surface of the base substrate 200.

The solar cell 250 shown in FIGS. 1 and 2 may be manufactured in the manner described above.

According to the present example embodiment, the first impurity may be implanted into the base substrate 200 at room temperature, so that the first doped region DP1 may be easily formed without a chamber and/or a doping device for heating up to a temperature of about 850° C. or higher. Although a laser beam is irradiated to the base substrate 200, a region irradiating the laser beam may be cooled by the first solution S1, making an additional cooling process with a refrigerant unnecessary. Thus, reliability of manufacturing the solar cell 250 and productivity of the solar cell 250 may be improved.

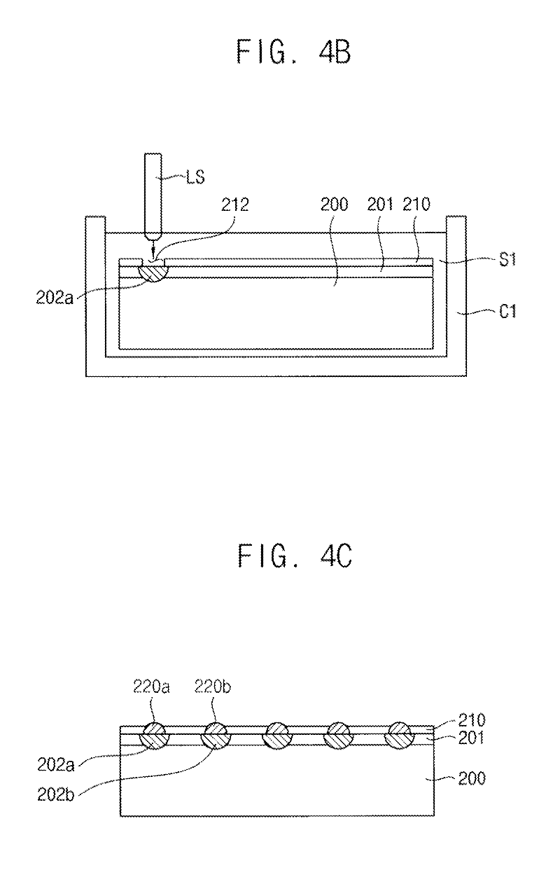

FIGS. 4A to 4C are cross-sectional views illustrating a method of manufacturing a solar cell according to another embodiment of the present invention.

Hereinafter, anther embodiment according to the present invention will be illustrated, referring to FIGS. 4A to 4C. A solar cell of this embodiment is substantially the same as the solar cell shown in FIGS. 1 and 2. Thus, any further repetitive description will be omitted and a method of manufacturing the solar cell according to the present embodiment will be illustrated.

Referring to FIG. 4A, a first doped layer 201 is formed on a first surface of a base substrate 200. The process for forming the first doped layer 201 is substantially the same as the process illustrated in FIG. 3A. Thus, any further repetitive description will be omitted. The first doped layer 201 is formed on substantially the entire first surface of the base substrate 200. For example, the first doped layer 201 including an n-type semiconductor may be formed on the base substrate 200 including a p-type semiconductor so that a PN junction may be defined.

An insulating layer 210 is formed on the base substrate 200 including the first doped layer 201 formed on the base substrate 200. The insulating layer 210 is formed on substantially the entire first surface of the base substrate 200.

Referring to FIG. 4B, the base substrate 200 including the insulating layer 210 formed on the base substrate 200 is disposed in a first container C1 receiving a first solution S1. The first solution S1 includes a first impurity. A first dopant generated from the first impurity may be an element of Group 15.

A laser beam is irradiated to the base substrate 200 while the base substrate is dipped into the first solution S1 using a laser irradiating device LS. The laser beam is irradiated to the base substrate 200 while the laser irradiating device LS moves along a first direction D1. An opening portion 212 is formed through the insulating layer 210 by the laser. The insulating layer 210 is partially removed by the laser to form the opening portion 212. The laser is irradiated to the insulating layer 210 while moving along the first direction D1 so that the opening portion 212 extends in the first direction D1. When the laser beam is continuously irradiated to a region corresponding to the opening portion 212 using the laser irradiating device LS, the first dopant generated from the first impurity is diffused into the base substrate 200. The first dopant locally diffuses into the region which corresponds to the opening portion 212 irradiating the laser beam. Thus, a first line 202a of first doped lines 202a and 202b may be formed on the first surface of the base substrate 200.

After shifting the laser irradiating device LS along a second direction D2, the laser beam is irradiated to the base substrate 200 that already has the first line 202a formed thereon while moving along the first direction D1 so that the opening portion 212 and a second line 202b of the first doped lines 202a and 202b are formed.

After forming the first doped lines 202a, 202b, the laser beam is irradiated to the base substrate 200 that is immersed in the first solution S1 while the laser irradiating device LS moves along the second direction D2, so that a first line 203a of second doped lines 203a and 203b may be formed, referring to FIGS. 1 and 2. In addition, after shifting the laser irradiating device LS in the first direction D1, the laser beam is irradiated to the base substrate 200 including the first line 202a while the laser irradiating device LS moves along the second direction D2 to form a second line 203b of the second doped lines 203a and 203b. The second line 203b of the second doped lines 203a and 203b is spaced apart from the first line 203a in the first direction D1.

As described, a first doped region DP1 including the first and second doped lines 202a, 202b, 203a and 203b may be formed on the first surface of the base substrate 200. The insulating layer 210 may be formed on substantially the entire first surface of the base substrate 200, and the first doped region DP1 may be exposed through the opening portion 212 of the insulating layer 210.

Referring to FIG. 4C, a first electrode EM is formed on the base substrate 200 including the insulating layer 210 having the opening portion 212 formed through the first surface of the base substrate 200. The first electrode EM may be formed using an electro coating method. A voltage is applied to the base substrate 200 including the insulating layer 210 with the opening portion 212. If the voltage is applied while the base substrate 200 remains immersed in a solution including silver ion (Ag⁺), the first doped region DP1 exposed by the opening portion 212 may have conductivity. Thus, the silver ion is selectively coated in the first doped region DP1. However, the base substrate 200 covered by the insulating layer 210 has insulating properties so that the silver ion is not coated on the base substrate 200 covered by the insulating layer 210. Therefore, the first electrode EM directly contacting the first doped region DP1 is selectively formed in the first doped region DP1.

Alternatively, the first electrode EM may be formed using the screen printing method illustrated in FIG. 3D.

As mentioned above in reference to FIG. 3E, a second electrode 240 is formed on a second surface of the base substrate 200 and the base substrate 200 including the second electrode 240 is heated to form a second doped layer 205. This way, the solar cell 250 shown in FIGS. 1 and 2 is manufactured.

According to the present embodiment, the first impurity may be implanted into the base substrate 200 at room temperature, so that the first doped region DP1 may be easily formed without a chamber and/or a doping device for heating up to a temperature more than or equal to about 850° C. In addition, the insulating layer 210 may be easily patterned using the laser in forming the first doped region DP1. Thus, reliability of manufacturing the solar cell 250 and a productivity of the solar cell 250 may be improved.

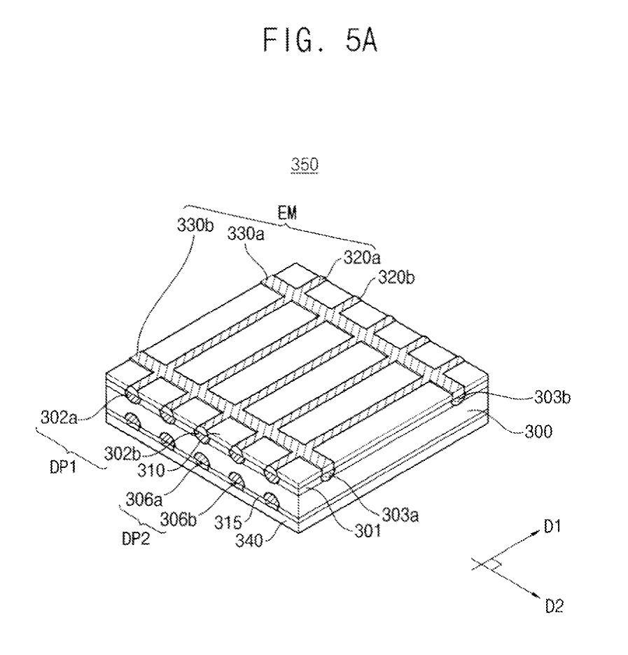

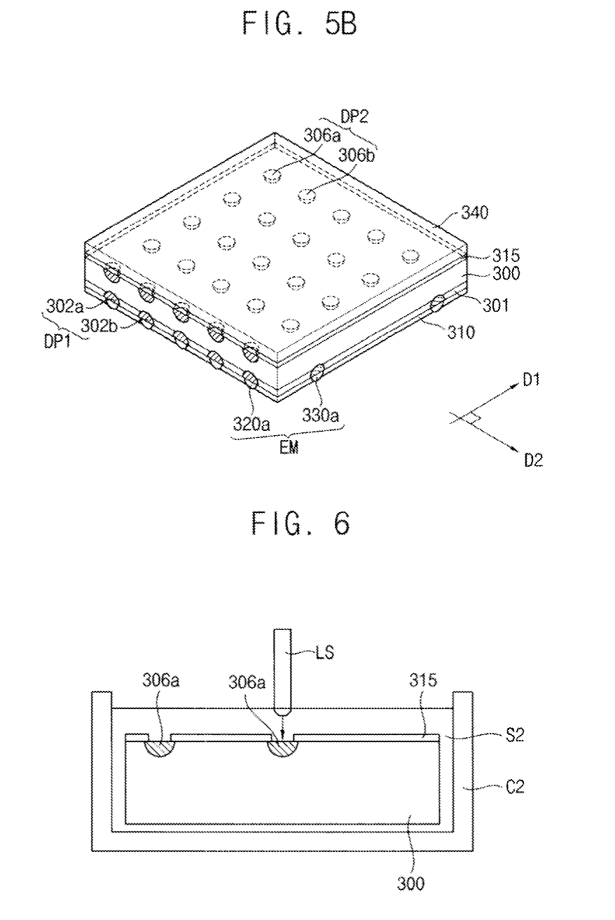

FIG. 5A is a perspective view illustrating a solar cell manufactured by a method according to still another embodiment of the present invention. FIG. 5B is a perspective view illustrating a rear side of the solar cell shown in FIG. 5A.

Referring to FIGS. 5A and 5B, a solar cell 350 according to the present embodiment includes a base substrate 300, a first electrode EM, an insulating layer 310, a cover layer 315 and a second electrode 340. The base substrate 300 includes a first doped region DP1 and first doped layer 301 which are formed on a first surface of the base substrate 300, and a second doped region DP2 formed on a second surface of the base substrate 300. The first electrode EM, the insulating layer 310, the cover layer 315 and the second electrode 340 are formed on the base substrate 300 including the first doped region DP1 and the second doped region DP2. In the present embodiment, the first surface of the base substrate 300 is a surface that receives sunlight in the solar cell 350.

The base substrate 300 may include a p-type semiconductor or an n-type semiconductor.

The first doped layer 301 may include an n-type semiconductor. The first doped region DP1 may include an n+ type semiconductor. The first doped region DP1 includes a plurality of first doped lines 302a and 302b extending in a first direction D1 and a plurality of second doped lines 303a and 303b extending in a second direction D2. The first doped layer 301, the first doped lines 302a and 302b and the second doped lines 303a and 303b are substantially the same as the first doped layer, and the first and second doped lines illustrated in FIGS. 1 and 2. Thus, any further repetitive description will be omitted.

The first electrode EM includes a plurality of finger lines 320a and 320b and a plurality of bus lines 330a and 330b. The first electrode EM is substantially the same as the first electrode illustrated in FIGS. 1 and 2. Thus, any further repetitive description will be omitted.

The second doped region DP2 may include a p+ type semiconductor. The second doped region DP2 includes a plurality of first doped dots 306a and 306b. Each of the first doped dots 306a and 306b has a dot shape when viewed in a plane and has a hemisphere shape when viewed in three dimensions. The first doped dots 306a and 306b may be arranged to have a matrix shape in the first and second directions. The second doped region DP2 functions as substantially the same as the second doped layer illustrated in FIGS. 1 and 2. The second doped region DP2 includes a plurality of the first doped dots 306a and 306b so that the second electrode 340 may make contact with the second doped region DP2. Thus, the first doped dots 306a and 306b may prevent the reliability of an electric connection between the second doped region DP2 and the second electrode 340 from being reduced due to crystal defects or sources of pollution.

The cover layer 315 is attached to the second surface of the base substrate 300. The cover layer 315 may include silicon nitride or silicon oxide. The cover layer 315 includes holes exposing each of the first doped dots 306a and 306. The first doped dots 306a and 306b may directly make contact with the second electrode 340 through the holes of the cover layer 315.

FIG. 6 is a cross-sectional view illustrating the method of manufacturing the solar cell shown in FIGS. 5A and 5B.

Referring to FIG. 6, the cover layer 315 is formed on the second surface of the base substrate 300, and the base substrate 300 including the cover layer 315 is disposed in a second container C2 holding a second solution S2. A laser beam is irradiated to the second surface of the base substrate 300 while the substrate 300 is dipped into the second solution S2, using a laser irradiating device LS. After disposing the laser irradiating device LS over the second surface of the base substrate 300 and stopping it over a specific region, the laser beam is locally irradiated to the specific region during a predetermined period. The cover layer 315 of the specific region irradiated by the laser is removed, and a second dopant generated from a second impurity of the second solution S2 may be implanted into the base substrate 300 exposed through the cover layer 315.

Examples of the second impurity may include boric acid, boron trichloride (BCl₃), diboron trioxide (B₂O₃), boron tribromide (BBr₃), boron trifluoride (BF₃), triethyl borate, ((C₂H₅O)₃B) and trimethyl borate (CH₃O)₃B), etc. The second dopant includes boron (B). Alternatively, examples of the second impurity may include aluminum sulfate (Al₂(SO₄)₂), aluminum chloride (AlCl₃), lithium aluminum hydride (LiAlH₄), aluminum chloride-lithium aluminum hydride (AlCl₃-LiAlH₄), aluminum chloride-1-ethyl-3-methylimidazolium chloride, aluminum chloride-trimethylphenylammonium chloride, aluminum chloride-n-butylpyridinium chloride, aluminum chloride-triethylamine hydrochloride, aluminum bromide (AlBr₃) and aluminum bromide-dimethylethylphenylammonium bromide, etc. In the present example embodiment, the second dopant includes aluminum (Al).

The laser irradiating device LS moves along the first direction D1 without irradiation, and the laser irradiating device LS stops over a specific region. The specific region of the second surface of the base substrate 300 is irradiated while the laser irradiating device LS is stopped. Then, the laser providing device moves along the second direction D2 without irradiating the base substrate 300, and the laser device LS is again stopped over another specific region to locally irradiate the base substrate 300. In this manner, holes are formed through the cover layer 315 and the first doped dots 306a and 306b are formed in regions corresponding to the holes.

Unlike the above-mentioned embodiment described in reference to FIG. 6, the base substrate 300 dipped into the second container C2 may include the first doped layer 301, the insulating layer 310 and the first doped region DP1. Forming the first doped layer 301, the insulating layer 310 and the first doped region DP1 on the base substrate 300 are substantially the same as the previous example embodiment illustrated in FIGS. 3A, 3B and 3C. Thus, any further repetitive description will be omitted.

When the first doped region DP1 is formed before forming the second doped region DP2, a cleaning process may be performed to remove any residual first solution S1 after taking out the base substrate 300 including the first doped region DP1 from the first container C1. During the cleaning process, the base substrate 300 including the first doped region DP1 is dipped into and pulled out of a container including distilled water. After the cleaning process, the base substrate 300 including the first doped region DP1 is disposed in the second container C2 to form the second doped region DP2 on the base substrate 300.

The first electrode EM is formed on the first surface of the base substrate 300 and the second electrode 340 is formed on the second surface of the base substrate 300. Forming the first electrode EM is substantially the same as the previous example embodiment illustrated in FIG. 3D. Thus, any further repetitive description will be omitted. The second electrode 340 is formed on the cover layer 315.

This way, the solar cell 350 shown in FIGS. 5A and 5B may be manufactured.

According to the present example embodiment, the first and second doped regions DP1 and DP2 may be easily formed without a chamber and/or a doping device for heating up to a temperature more than or equal to about 850° C. In addition, the first and second doped regions DP1 and DP2 may be formed on the base substrate 300 without using a mask to simplify processes for manufacturing the solar cell 350. Thus, reliability of manufacturing the solar cell 350 and a productivity of the solar cell 350 may be improved.

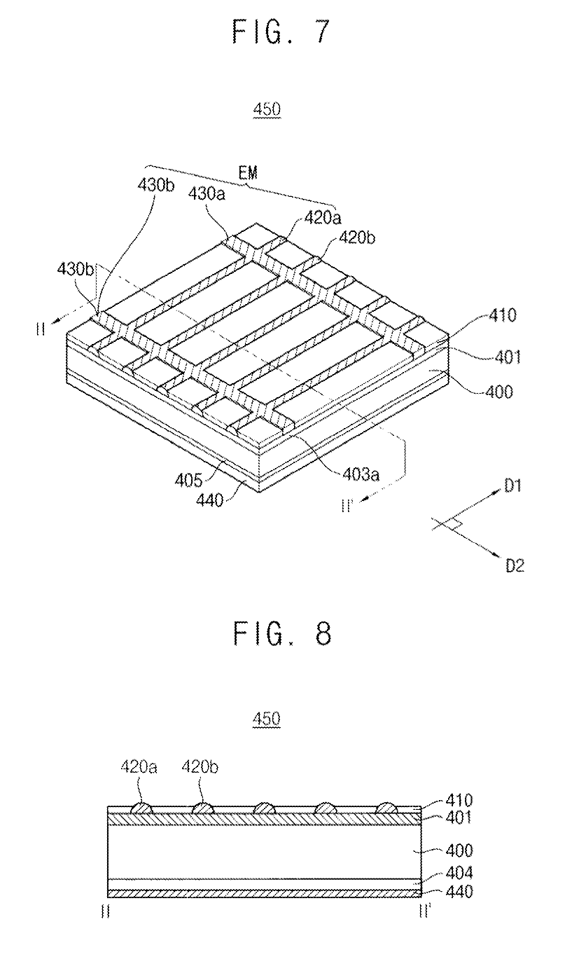

FIG. 7 is a perspective view illustrating a solar cell manufactured by a method according to still another example embodiment of the present invention.

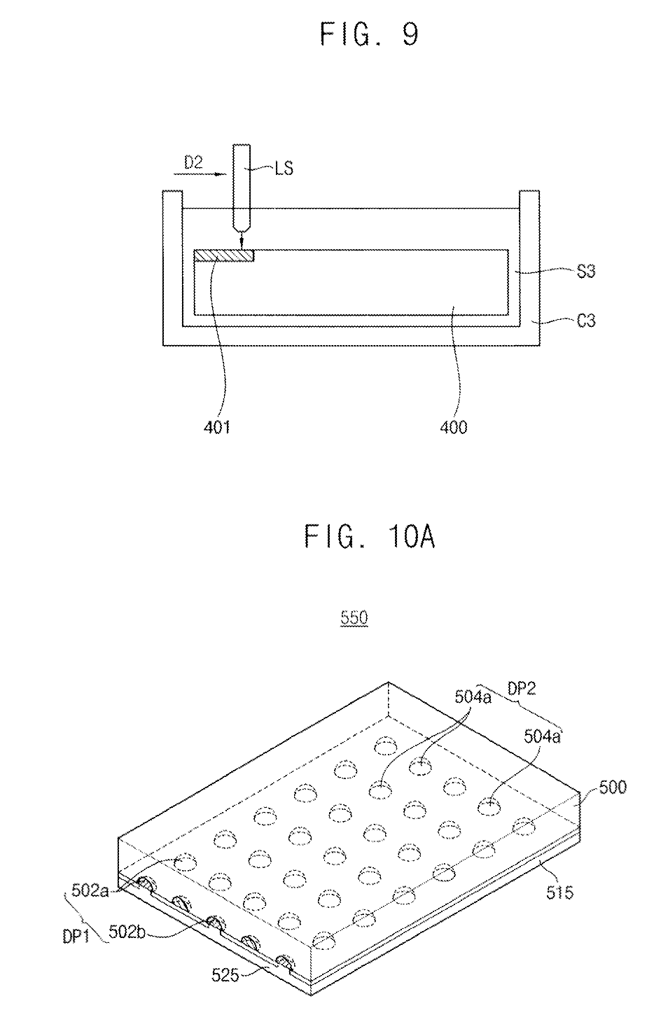

FIG. 8 is a cross-sectional view taken along a line II-II′ in FIG. 7.

Referring to FIGS. 7 and 8, a solar cell 450 according to the present example embodiment includes a base substrate 400, a first electrode EM, a second electrode 440 and an insulating layer 410. The base substrate 400 includes a first doped layer 401 and a second doped layer 405. The first electrode EM, the second electrode 440 and the insulating layer 410 are formed on the base substrate 400 including the first doped layer 401 and the second doped layer 405.

The base substrate 400 may include a p-type semiconductor.

The first doped layer 401 may include an n-type semiconductor. The first doped layer 401 is formed on a first surface of the base substrate 400. The first surface of the base substrate 400 is the surface receiving sunlight in the solar cell 450. The base substrate 400 includes a p-type semiconductor and the first doped layer 401 includes an n-type semiconductor so that a PN junction may be defined. The first doped layer 401 substantially receives the sunlight and functions as an emitter. The first doped layer 401 is formed on substantially the entire first surface of the base substrate 400.

The first electrode EM is formed on the first doped layer 401. The first electrode EM includes a plurality of finger lines 420a and 420b and a plurality of bus lines 430a and 430b. The finger lines 420a and 420b and the bus lines 430a and 430b are substantially the same as the finger lines 220a and 220b and the bus lines 230a and 230b illustrated in FIGS. 1 and 2 except for being formed on the first doped layer 401. Thus, any further repetitive description will be omitted.

The insulating layer 410 is formed on the first doped layer 401 except for a region in which the first electrode EM is formed. The insulating layer 410 may function as a reflection blocking layer which minimizes reflection of the sunlight that is irradiated to the first doped layer 401.

The second doped layer 405 covers substantially the entire second surface of the base substrate 400. The second electrode 440 is formed on the second surface of the base substrate 400. The second doped layer 405 and the second electrode 440 are substantially the same as the second doped layer 205 and the second electrode 240 illustrated in FIGS. 1 and 2, respectively. Thus, any further repetitive description will be omitted.

Alternatively, the base substrate 400 may include an n-type semiconductor, the first doped layer 401 may include a p-type semiconductor and the second doped layer 405 may include an n+ type semiconductor.

FIG. 9 is a cross-sectional view illustrating the method of manufacturing the solar cell shown in FIG. 8.

Referring to FIGS. 8 and 9, the base substrate 400 is dipped into a first solution S1, and a laser beam is irradiated to a first surface of the base substrate 400 that is dipped into the first solution S1 using a layer irradiating device LS. The laser irradiating device LS scans the entire first surface so that the entire surface of the base substrate 400 is irradiated. For example, after the laser beam is irradiated to a specific region of the base substrate 400 while the laser irradiating device LS moves along a first direction D1, the laser irradiating device LS is moved in a second direction D2 different from the first direction D1 to be disposed over a region adjacent to the specific region. The laser beam is irradiated to the base substrate 400 while the laser irradiating device LS that is shifted in the second direction D2 moves along the first direction D1. The above moving and shifting are repeatedly performed, so that substantially the entire base substrate 400 is scanned by the laser irradiating device LS. The first doped layer 401 may be formed on substantially the entire first surface of the base substrate 400.

The insulating layer 410 and the first electrode EM are sequentially formed on the first surface of the base substrate 400 including the first doped layer 401. In addition, the second electrode 450 is formed on the second surface of the base substrate 400. The base substrate 400 including the second electrode 450, the insulating layer 410 and the first electrode EM is heated to directly make contact with the first electrode EM and the first doped layer 401. In addition, by heating the base substrate 400, the second doped layer 405 is formed between the second surface of the base substrate 400 and the second electrode 450.

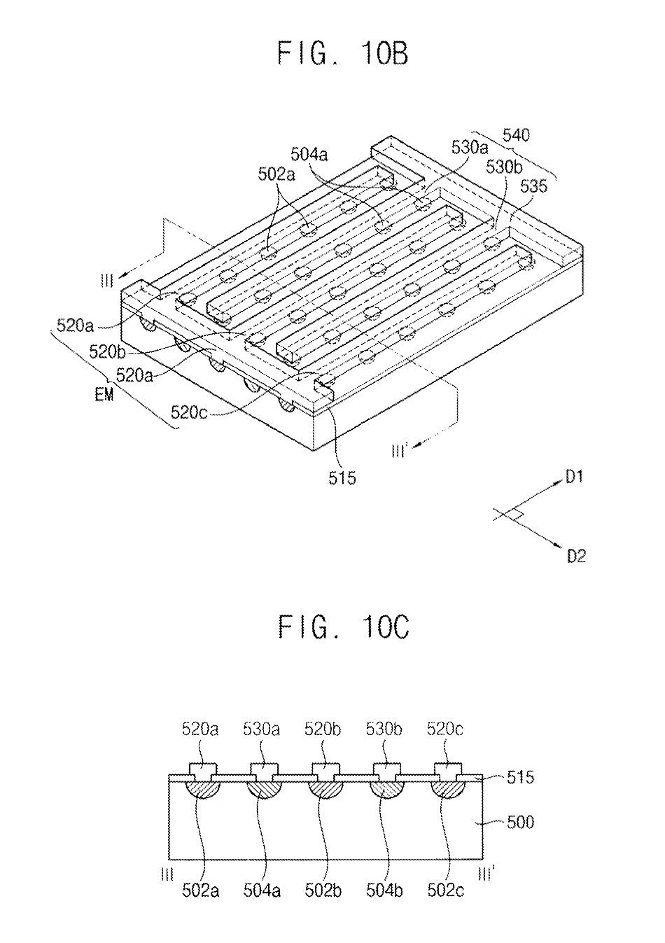

FIG. 10A is a perspective view illustrating a solar cell manufactured by a method according to still another example embodiment of the present invention. FIG. 10B is a perspective view illustrating a rear side of the solar cell shown in FIG. 10A. FIG. 10C is a cross-sectional view taken along a line III-III′ in FIG. 10B.

Referring to FIGS. 10A, 10B and 10C, a solar cell 550 according to the present example embodiment includes a base substrate 500, a cover layer 515, a first electrode EM and a second electrode 540. The base substrate 500 includes a first doped region DP1 and a second dope region DP2. The cover layer 515 is formed in the first and second doped regions DP1 and DP2. The first and second electrodes EM and 540 are formed on the base substrate 500 including the cover layer 515 formed on the base substrate 500 including the first and second doped regions DP1 and DP2. The first and second doped regions DP1 and DP2, and the first and second electrodes EM and 540 are formed on a second surface opposite to a first surface of the base substrate 500. The sunlight is incident on the first surface of the base substrate 500.

The base substrate 500 may include a p-type semiconductor or an n-type semiconductor.

The first doped region DP1 may include an n+ type semiconductor. The first doped region DP1 includes a plurality of first doped dots 502a, 502b and 502c. In the first doped dots 502a, 502b and 502c (see FIG. 10C), the first doped dots 502a disposed in a first row extending in a first direction D1 are spaced apart from each other along the first direction D1. In addition, the first doped dots 502b disposed in a second row disposed in a second direction D2 of the first row are spaced apart from each other along the first direction D1. The first doped dots 502a in the first row are disposed adjacent to the first doped dots 502b in the second row along the second direction D2.

The second doped region DP2 may include a p+ type semiconductor. The second doped region DP2 includes a plurality of second doped dots 504a and 504b. In the second doped dots 504a and 504b, the second doped dots 504a between the first row of the first doped dots 502a and the second row of the first doped dots 502b are arranged along the first direction D1 to define a third row. In addition, the second doped dots 504b between the second row of the first doped dots 502b and a fourth row of the second doped dots 504b is arranged along the first direction D1 to define a fifth row. The second doped dots 504a of the third row are disposed adjacent to the fifth row of the second doped dots 504b along the second direction D2.

The first and second doped regions DP1 and DP2 are alternately and repetitively arranged along the second direction D2, so that a potential difference between the first and second doped regions DP1 and DP2 is generated by the sunlight to generate electric power. Each of the first and second doped regions DP1 and DP2 includes a plurality of the doped dots so that the first doped region DP1 may make contact with the first electrode EM1 and the second doped region DP2 may make contact with the second electrode 540. Thus, the doped dots may prevent the reliability of an electric connection between the first doped region DP1 and the first electrode EM or between the second doped region DP2 and the second electrode 540 from being reduced due to crystal defects or sources of pollution.

The first electrode EM includes a plurality of first line electrodes 520a, 520b and 520c and a first connection electrode 525 connecting the first line electrodes 520a, 520b and 520c to each other. The first line electrodes 520a, 520b and 520c extend in the first direction D1. For example, each of the line electrodes 520a, 520b and 520c extends in the first direction D1 to make contact with the first doped dots 502a, 502b and 502c arranged along the first row, the second row and the fourth row.

The second electrode 540 includes a plurality of second line electrodes 530a and 530b and a second connection electrode 535 connecting the second line electrodes 530a and 530b to each other. The second line electrodes 530a and 530b extend in the first direction D1 and are spaced apart from each other. The second line electrodes 530a and 530b make contact with the second doped dots 504a and 504b. The second connection electrode 535 extends in the second direction D2 substantially parallel to the first connection electrode 525.

The width of each of the first line electrodes 520a, 520b and 520c and the second line electrodes 530a and 530b is substantially the same as or less than a diameter of each of the first doped dots 502a, 502b and 502c and the second doped dots 504a and 504b. When the width is greater than the diameter, an electric resistance may be increased or an adjustment of a voltage distribution between the first and second dope regions DP1 and DP2 may be hard to be controlled.

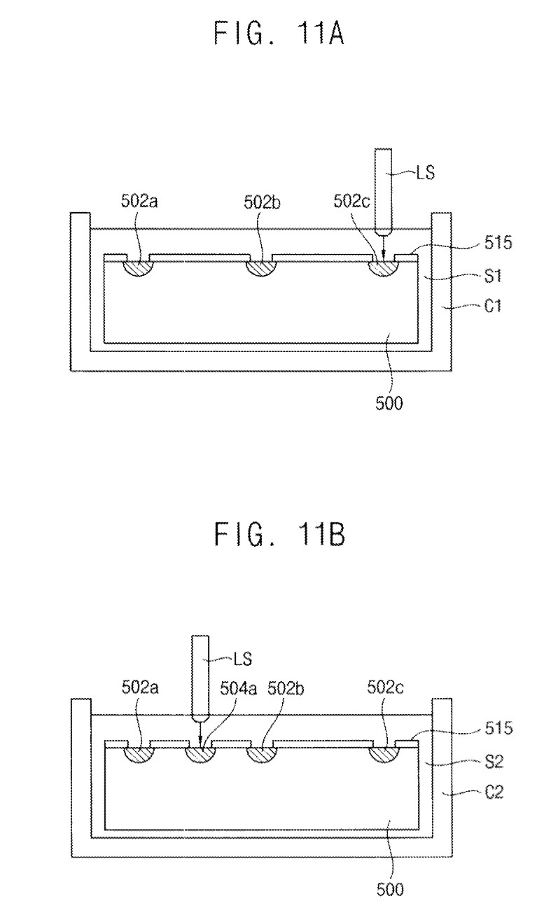

FIGS. 11A and 11B are cross-sectional views illustrating the method of the solar cell shown in FIG. 10C.

Referring to FIG. 11A, the base substrate 500 including the cover layer 515 formed on the second surface of the base substrate 500 is dipped into a first solution S1, for example by being disposed in a first container C1 holding the first solution S1. A laser beam is irradiated to the second surface of the base substrate 500 while the substrate 500 is immersed in the first container C1, by using a laser irradiating device LS. The laser beam is irradiated to the base substrate 500 while the laser irradiating device LS is stopped. Thus, a hole is formed in a region of the cover layer 515 irradiated by the laser so that a first dopant may be implanted into the base substrate 500 via the hole. The laser irradiating device LS moves in the first direction D1 without any irradiation, and the laser irradiating device LS irradiates the base substrate 500 after being stopped at a predetermined location above the base substrate 500 with the laser beam. After the first doped dots 502a of the first row are formed, the laser irradiating device LS is moved a predetermined distance in the second direction D2, and the first doped dots 502b of the second row are formed by repeating the steps that were used for forming the first doped dots 502a of the first row.

The first solution S1 includes a first impurity generating the first dopant. Examples of the first impurity may include phosphorus pentoxide (P2O5), phosphoric acid (H3PO4), triethyl phosphite ((C2H5O)3P) or trimethyl phosphite ((CH3O)3P), etc. In the present embodiment, the first dopant includes phosphorus (P).

After forming the first doped region DP1 including the first doped dots 502a, 502b and 502c, a cleaning process may be performed to remove any residual first solution S1 that remains after pulling out the base substrate 500 from the first container C1. During the cleaning process, the base substrate 500 including the first doped region DP1 is dipped into and taken out of a container including distilled water.

Referring to FIG. 11B, the base substrate 500 including the first doped region DP1 is disposed in a second container C2 holding a second solution S2. The laser beam is irradiated to the base substrate 500 immersed in the second solution S2 using the laser irradiating device LS. A second dopant generated from a second impurity of the second solution S2 may be implanted into a region of the base substrate 500 irradiated by the laser by the laser irradiating device LS. The laser irradiating device LS irradiates the laser to regions between the first doped dots 502a and 502b adjacent to each other in the second direction D2 and not to where the first doped region DP1 is formed. Thus, the second doped dots 504a and 504b are disposed between the first doped dots 502a, 502b and 502c so that the second doped region DP2 may be formed on the second surface of the base substrate 500.

Examples of the second impurity may include boric acid, boron trichloride (BCl3), diboron trioxide (B2O3), boron tribromide (BBr3), boron trifluoride (BF3), triethyl borate, ((C2H5O)3B) and trimethyl borate (CH3O)3B), etc. In the present embodiment, the second dopant includes boron (B). Alternatively, examples of the second impurity may include aluminum sulfate (Al2(SO4)2), aluminum chloride (AlCl3), lithium aluminum hydride (LiAlH4), aluminum chloride-lithium aluminum hydride (AlCl3-LiAlH4), aluminum chloride-1-ethyl-3-methylimidazolium chloride, aluminum chloride-trimethylphenylammonium chloride, aluminum chloride-n-butylpyridinium chloride, aluminum chloride-triethylamine hydrochloride, aluminum bromide (AlBr3) and aluminum bromide-dimethylethylphenylammonium bromide, etc. In the present embodiment, the second dopant includes aluminum (Al).

The first electrode EM and the second electrode 540 are formed on the base substrate 500 including the first and second doped regions DP1 and DP2 and the cover layer 515 formed on the base substrate 500. Processes for forming the first and second electrodes EM and 540 are substantially the same as in the example embodiment illustrated in FIG. 3D. Thus, any further repetitive descriptions will be omitted.

This way, the solar cell 550 shown in FIGS. 10A, 10B and 10C may be manufactured.

According to the present example embodiment, the first and second doped regions DP1 and DP2 may be formed without using a chamber and/or a doping device for heating up to a temperature more than or equal to about 850° C. In addition, the first and second doped regions DP1 and DP2 may be formed on the base substrate 500 without using a mask to simplify the processes for manufacturing the solar cell 550 and to improve alignment reliability of the first and second doped regions DP1 and DP2. Thus, reliability of manufacturing the solar cell 550 and productivity of the solar cell 550 may be improved.

The method for implanting impurities into the substrate and the method for manufacturing a solar cell using the method according to the present invention may be generally used with a semiconductor technology including a doping process.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention.

What is claimed is:

1. A method for implanting impurities into a substrate, the method comprising:
dipping a substrate into a first solution including a first impurity; and
irradiating a laser beam to a first region of the substrate dipped into the first solution to implant a first dopant generated from the first impurity into the first region.

2. The method of claim 1, wherein each of dipping the substrate and irradiating the laser beam is performed at room temperature.

3. The method of claim 1, wherein the first impurity comprises one or more of boric acid, boron trichloride (BCl₃), diboron trioxide (B₂O₃), boron tribromide (BBr₃), boron trifluoride (BF₃), triethyl borate ((C₂H₅O)₃B), trimethyl borate ((CH₃O)₃B), aluminum sulfate (Al₂(SO₄)₂), aluminum chloride (AlCl₃), lithium aluminum hydride (LiAlH₄), aluminum chloride-lithium aluminum hydride (AlCl₃-LiAlH₄), aluminum chloride-1-ethyl-3-methylimidazolium chloride, aluminum chloride-trimethylphenylammonium chloride, aluminum chloride-n-butylpyridinium chloride, aluminum chloride-triethylamine hydrochloride, aluminum bromide (AlBr₃) and aluminum bromide-dimethylethylphenylammonium bromide.

4. The method of claim 1, wherein the first impurity comprises one or more of phosphorus pentoxide (P₂O₅), phosphoric acid (H₃PO₄), triethyl phosphite ((C₂H_{S}O)₃P) and trimethyl phosphite ((CH₃O)₃P).

5. The method of claim 1, further comprising:
irradiating the laser beam to an entire surface of the substrate to form a doped layer on substantially the entire surface of the substrate before implanting the first dopant.

6. The method of claim 1, further comprising forming an insulating layer on the substrate before dipping the substrate into the first solution,
wherein the first dopant is diffused into the first region from which the insulating layer is removed by the laser.

7. The method of claim 1, further comprising:
dipping the substrate including the first region doped with the first dopant into a second solution including a second impurity; and
irradiating a laser beam to a second region adjacent to the first region of the substrate dipped into the second solution to implant a second dopant generated from the second impurity into the second region.

8. The method of claim 1, wherein the laser beam is locally irradiated to the first region.

9. The method of claim 1, wherein the laser beam is continuously irradiated to the substrate while moving in a preselected direction on the substrate, and the first region has a stripe shape extending in the preselected direction.

10. A method of manufacturing a solar cell, the method comprising:
dipping a substrate into a first solution including a first impurity;
irradiating a laser beam to a first surface of the substrate with a laser dipped into the first solution to form a first doped region doped with a first dopant generated from the first impurity;
forming a first electrode making contact with the first doped region; and
forming a second electrode on the substrate.

11. The method of claim 10, wherein the first doped region is formed by irradiating the laser to substantially the entire first surface of the substrate.

12. The method of claim 10, wherein irradiating the laser beam to substantially the entire first surface comprises:
irradiating the laser beam to the first surface of the substrate while moving a laser irradiating device along a first direction on the substrate;
moving the laser irradiating device in a second direction different from the first direction over the first surface; and
irradiating the laser beam to the first surface along the first direction using the laser irradiating device transferred to the second direction.

13. The method of claim 12, further comprising:
irradiating the laser beam to an entire surface of the substrate to form a first doped layer on the entire surface of the substrate before dipping the substrate into the first solution.

14. The method of claim 10, further comprising forming an insulating layer on the first surface before dipping the substrate into the first solution,
wherein the first dopant is diffused into a region in which the insulating layer is removed by the laser to form the first doped region.

15. The method of claim 14, wherein the first electrode is selectively formed in the first doped region exposed by removing the insulating layer.

16. The method of claim 10, wherein the first electrode is formed by:
forming an insulating layer on the substrate including the first doped region;
forming the first electrode on the insulating layer formed on the substrate;
heating the substrate including the first electrode formed on the substrate; and
diffusing a metal of the first electrode into the insulating layer in a region making contact with the first electrode so that the first electrode and the first doped region make contact with each other.

17. The method of claim 10, wherein the second electrode is formed by:
heating the substrate including the second electrode formed on a second surface of the substrate; and
diffusing a metal of the second electrode to the second surface of the substrate to form a second doped layer between the first substrate and the second electrode.

18. The method of claim 10, further comprising:
dipping the substrate including the first doped region into a second solution including a second impurity different from the first impurity before forming the first electrode; and
irradiating the laser beam to the substrate dipped into the second solution to implant a second dopant generated from the second impurity and to form a second doped region adjacent to the first doped region.

19. The method of claim 18, wherein each of the first and second doped regions is formed by irradiating the laser beam to the substrate while a laser irradiating device irradiating the laser moves in a preselected direction along the substrate.

20. The method of claim 18, wherein each of the first and second doped regions is formed by:
irradiating the laser beam to the substrate while a laser irradiating device irradiating the laser is stopped at a predetermined position; and
moving the laser irradiating device to another predetermined position over the substrate.
